(19) United States
(12) Patent Application Publication
(10) Pub. No.: US 2022/0137520 A1
(43) Pub. Date: May 5, 2022

(54) EXPOSURE METHOD AND EXPOSURE DEVICE

(71) Applicant: CHANGXIN MEMORY TECHNOLOGIES, INC., Hefei (CN)

(72) Inventor: Xiaofang ZHOU, Hefei (CN)

(21) Appl. No.: 17/580,778

(22) Filed: Jan. 21, 2022

Related U.S. Application Data
(63) Continuation of application No. PCT/CN2021/097398, filed on May 31, 2021.

(30) Foreign Application Priority Data
Jul. 7, 2020 (CN) 202010647419.1

(51) Int. Cl. G03F 7/20

(52) U.S. Cl. CPC G03F 7/70525

(57) ABSTRACT

Provided are an exposure method and an exposure device. The method includes: extracting an exposure rule of a first layer pattern or a previous layer pattern of each wafer in the current wafer group; acquiring the serial number of at least one absent wafer in the current wafer group according to actual exposure information of the current layer pattern of each wafer in the current wafer group; removing the serial number of at least one absent wafer in the exposure rule of the current layer pattern, sequentially advancing the serial number of a wafer having the serial number posterior to the serial number of each of the at least one absent wafer in a sequence corresponding to the same bearing platform, and filling serial number vacancies to obtain the exposure rule of the current layer pattern; and exposing the current layer pattern of each wafer in the current wafer group.

### CROSS-REFERENCE TO RELATED APPLICATION(S)

This application is continuation of international application PCT/CN2021/097398, filed on May 31, 2021, which claims priority to Chinese patent application No. 202010647419.1, filed on Jul. 7, 2020 and entitled “EXPOSURE METHOD AND EXPOSURE DEVICE”. The contents of international application PCT/CN2021/097398 and Chinese patent application No. 202010647419.1 are hereby incorporated by reference in their entireties.

### TECHNICAL FIELD

This disclosure relates to the technical field of photolithography, and in particular to an exposure method and an exposure device.

### BACKGROUND

An exposure machine can project the pattern on a photomask onto a substrate coated with photoresist, so that a film layer on the substrate can be patterned through the subsequent developing and etching processes. The exposure machine is currently widely used in the field of integrated circuit manufacturing.

In the related art, the exposure machine sequentially exposes each wafer in a wafer group according to a preset sequence. When an absent wafer appears in the wafer group, no wafer is exposed on a bearing platform of the exposure machine corresponding to the absent wafer, so that the effective exposure time of the exposure machine is shortened, the number of exposed wafers in unit time is reduced, and the productivity of the exposure machine is reduced.

### SUMMARY

In the first aspect, an embodiment of the disclosure provides an exposure method, which is executed by the exposure machine. The exposure machine includes a first bearing platform and a second bearing platform. The first bearing platform and the second bearing platform work alternately. The exposure method includes the following steps. An exposure rule of a first layer pattern or a previous layer pattern of each wafer in the current wafer group is extracted, where the exposure rule includes correspondences between wafer serial numbers and bearing platforms, and the sequence of the wafer serial numbers identifies the exposure sequence of the corresponding wafers. The serial number of at least one absent wafer in the current wafer group according to the actual exposure information of the current layer pattern of each wafer in the current wafer group. The serial number of at least one absent wafer in the exposure rule of the current layer pattern is removed, the serial number of a wafer having the serial number posterior to the serial number of each of at least one absent wafer in a sequence corresponding to the same bearing platform is sequentially advanced, and serial number vacancies are filled to obtain the exposure rule of the current layer pattern. The current layer pattern of each wafer in the current wafer group is exposed according to the exposure rule of the current layer pattern.

In the second aspect, an embodiment of the disclosure further provides an exposure device, arranged in an exposure machine. The exposure machine includes a first bearing platform and a second bearing platform, the first bearing platform and the second bearing platform work alternately. The exposure device comprises a processor and a memory storing a computer program executable by the processor. when executing the computer program, the processor is configured to: extract an exposure rule of a first layer pattern or a previous layer pattern of each wafer in a current wafer group, wherein the exposure rule comprises correspondences between wafer serial numbers and bearing platforms, and a sequence of the wafer serial numbers identifies an exposure sequence of corresponding wafers; acquire a serial number of at least one absent wafer in the current wafer group according to actual exposure information of a current layer pattern of each wafer in the current wafer group; remove the serial number of the at least one absent wafer in the exposure rule of the current layer pattern, sequentially advance a serial number of a wafer having the serial number posterior to the serial number of each of the at least one absent wafer in a sequence corresponding to a same bearing platform, and fill serial number vacancies to obtain the exposure rule of the current layer pattern; and expose the current layer pattern of each wafer in the current wafer group according to the exposure rule of the current layer pattern.

In the third aspect, an embodiment of the disclosure further provides a non-volatile computer-readable storage medium, applied to an exposure machine. The exposure machine comprises a first bearing platform and a second bearing platform, the first bearing platform and the second bearing platform work alternately. The storage medium stores a computer program. When executed by a processor arranged in the exposure machine, the computer program is configured to: extract an exposure rule of a first layer pattern or a previous layer pattern of each wafer in a current wafer group, wherein the exposure rule comprises correspondences between wafer serial numbers and bearing platforms, and a sequence of the wafer serial numbers identifies an exposure sequence of corresponding wafers; acquire a serial number of at least one absent wafer in the current wafer group according to actual exposure information of a current layer pattern of each wafer in the current wafer group; remove the serial number of the at least one absent wafer in the exposure rule of the current layer pattern, sequentially advance a serial number of a wafer having the serial number posterior to the serial number of each of the at least one absent wafer in a sequence corresponding to a same bearing platform, and fill serial number vacancies to obtain the exposure rule of the current layer pattern; and expose the current layer pattern of each wafer in the current wafer group according to the exposure rule of the current layer pattern.

### BRIEF DESCRIPTION OF THE DRAWINGS

Other features, objects and advantages of the disclosure will become more apparent upon reading of the following detailed description of non-limiting embodiments thereof with reference to the accompanying drawings, among which:

FIG. 1 illustrates a flowchart of an exposure method provided in an embodiment of the disclosure;

FIG. 2 illustrates a diagram of correspondences between bearing platforms and wafer serial numbers provided in an embodiment of the disclosure;

FIG. 3 illustrates a diagram of correspondences between bearing platforms and wafer serial numbers provided in another embodiment of the disclosure;

FIG. 4 illustrates a diagram of correspondences between bearing platforms and wafer serial numbers provided in yet another embodiment of the disclosure;

FIG. 5 illustrates a schematic diagram of an exposure device provided in an embodiment of the disclosure.

### DETAILED DESCRIPTION

To further explain the technical means and effects adopted by the disclosure to achieve the intended purpose, the detailed description is given hereinafter for the specific implementation modes, structures, features and effects of an exposure method and an exposure device proposed by the disclosure with reference to accompanying drawings and embodiments.

An embodiment of the disclosure provides an exposure method, which is executed by an exposure machine. The exposure machine includes a first bearing platform and a second bearing platform. The first bearing platform and the second bearing platform work alternately. The exposure method includes the following steps. An exposure rule of a first layer pattern or a previous layer pattern of each wafer in the current wafer group is extracted, where the exposure rule includes correspondences between wafer serial numbers and bearing platforms, and the sequence of the wafer serial numbers identifies the exposure sequence of the corresponding wafers.

The serial number of at least one absent wafer in the current wafer group according to the actual exposure information of the current layer pattern of each wafer in the current wafer group.

The serial number of at least one absent wafer in the exposure rule of the current layer pattern is removed, the serial number of a wafer having the serial number posterior to the serial number of each of the at least one absent wafer in a the sequence corresponding to the same bearing platform is sequentially advanced, and serial number vacancies are filled to obtain the exposure rule of the current layer pattern.

The current layer pattern of each wafer in the current wafer group is exposed according to the exposure rule of the current layer pattern.

According to the technical scheme of the embodiments of the disclosure, the exposure rules of the first layer pattern or the previous layer pattern of each wafer in the current wafer group is extracted, where the exposure rules include the correspondences between the wafer serial numbers and bearing platforms, and the sequence of the wafer serial numbers identifies the exposure sequence of the corresponding wafers; the serial number of at least one absent wafer in the current wafer group is acquired according to the actual exposure information of the current layer pattern of each wafer in the current wafer group; the serial number of at least one absent wafer in the exposure rule of the current layer pattern is removed, the serial number of the wafer having the serial number posterior to the serial number of each of at least one absent wafer in the sequence corresponding to the same bearing platform is sequentially advanced, and the serial number vacancies are filled to obtain the exposure rule of the current layer pattern; and the current layer pattern of each wafer in the current wafer group is exposed according to the exposure rule of the current layer pattern, so that when there is an absent wafer, the wafers behind the absent wafer for the same bearing platform are sequentially exposed in advance, the situation that the bearing platforms are empty is avoided, and the productivity of the exposure machine is improved.

The above is the core idea of the disclosure. The technical scheme in the embodiments of the disclosure will be clearly and completely described below with reference to the drawings in the embodiments of the disclosure. Apparently, the described embodiments are only part of the embodiments of the disclosure, rather than all of the embodiments. All other embodiments obtained by a person of ordinary skill in the art based on the embodiments of the disclosure without any creative effort belong to the protection scope of the disclosure.

In the following description, numerous specific details are set forth in order to provide a thorough understanding of the disclosure, and the disclosure may be implemented in other embodiments different from the specific details disclosed herein, those skilled in the art should appreciate that they can give an analogy in case of no prejudice to the connotation of the disclosure, and the disclosure is not limited by the specific embodiments disclosed below.

Next, the disclosure will be described in detail with reference to the drawings. In the detailed description of the embodiments of the disclosure, the drawings showing the structure of the device are not partially enlarged in general scale for the convenience of description, and the drawings are only examples, and should not limit the protection scope of the disclosure. In addition, the three-dimensional dimensions of length, width and height should be included in the actual production.

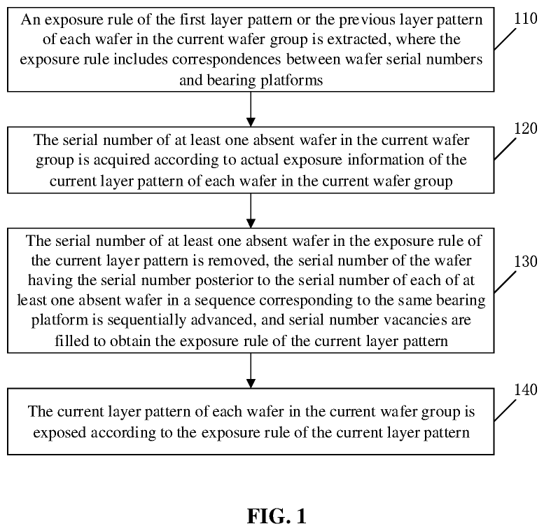

FIG. 1 illustrates a flowchart of an exposure method provided in an embodiment of the disclosure. The exposure method is executed by an exposure machine. The exposure machine includes a first bearing platform and a second bearing platform, and the first bearing platform and the second bearing platform work alternately. Specifically, as shown in FIG. 1, the exposure method includes the following steps.

At 110, an exposure rule of the first layer pattern or the previous layer pattern of each wafer in the current wafer group is extracted, where the exposure rule includes correspondences between wafer serial numbers and bearing platforms, and the sequence of the wafer serial numbers identifies the exposure sequence of the corresponding wafers.

The first layer pattern is a pattern of the first exposure of each wafer in the current wafer group, namely a pattern exposed before any other patterns. The previous layer pattern is a pattern of the previous exposure with respect to the current layer pattern in the current wafer group. In addition, the current layer pattern is a pattern to be exposed in the current wafer group.

In some embodiments, the wafer serial numbers corresponding to the same bearing platform are sequentially increased, and the wafer serial numbers corresponding to the first bearing platform and the second bearing platform, which are alternately arranged in the exposure rule of the first layer pattern or the previous layer pattern, are sequentially increased.

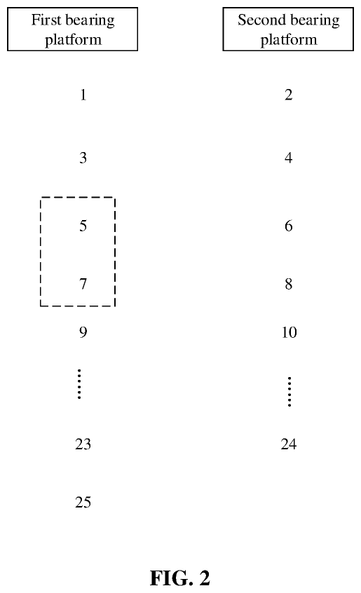

Exemplarily, FIG. 2 illustrates a diagram of correspondences between bearing platforms and wafer serial numbers provided in an embodiment of the disclosure. FIG. 2 provides illustration instead of limitation by taking the current wafer group including 25 wafers as an example; and in other implementation modes of the present embodiment, the number of wafers in the current wafer group may also be other values. Referring to FIG. 2, wafers numbered 1, 2, 3 . . . 23, 24 and 25 alternately correspond to the first bearing platform and the second bearing platform according to the sequence of the wafer serial numbers. In the actual exposure process, the wafers numbered 1, 2, 3 . . . 23, 24 and 25 are alternately exposed by using the first bearing platform and the second bearing platform in turn. Specifically, the wafer numbered 1 is exposed on the first bearing platform, the wafer numbered 2 is exposed on the second bearing platform, the wafer numbered 3 is exposed on the first bearing platform, the wafer numbered 4 is exposed on the second bearing platform, and so on, and the wafers numbered 5, 6, 7 . . . 23, 24 and 25 are exposed on the first bearing platform and the second bearing platform alternately in turn.

At 120, the serial number of at least one absent wafer in the current wafer group is acquired according to actual exposure information of the current layer pattern of each wafer in the current wafer group.

It should be noted that, when there are absent wafers in the current wafer group, and when the current layer pattern of each wafer in the current wafer group is used to expose the absent wafers, there is no wafer for exposure on the bearing platform corresponding to the absent wafers, which results in a reduction in the productivity of the exposure machine.

Exemplarily, with continued reference to FIG. 2, the determined absent wafers may be, for example, wafers numbered 5 and 7, respectively. In FIG. 2, the serial numbers of the absent wafers are identified with dashed boxes. After the wafer numbered 4 is exposed on the second bearing platform, since the wafer numbered 5 is absent, there will be no wafers on the first bearing platform for exposure, the wafer numbered 6 is continued to be exposed on the second bearing platform. Actions such as alignment and correction need to be performed on the wafer numbered 6 on the second bearing platform before exposure. These actions results in time consumption, and the exposure machine cannot perform continuous exposure.

It is worth noting that different layer patterns of the same wafer are exposed by using the same bearing platform so as to reduce the alignment error of different layers. Therefore, by comparing the serial number of the wafer corresponding to the first layer pattern or the previous layer pattern with the serial number of the wafer corresponding to the current layer pattern, the serial number of the absent wafer corresponding to the current layer pattern can be determined, such as serial numbers 5 and 7 in FIG. 2.

At 130, the serial number of at least one absent wafer in the exposure rule of the current layer pattern is removed, the serial number of the wafer having the serial number posterior to the serial number of each of at least one absent wafer in a sequence corresponding to the same bearing platform is sequentially advanced, and serial number vacancies are filled to obtain the exposure rule of the current layer pattern.

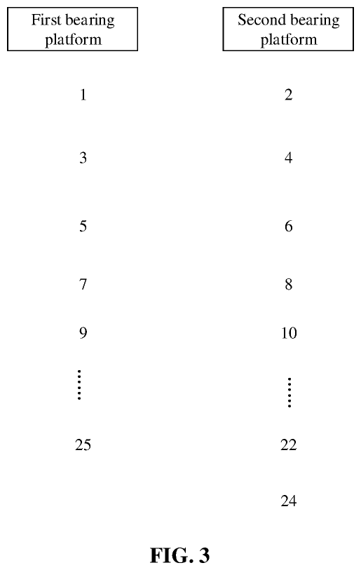

As shown in FIG. 2, the serial numbers of the absent wafers are removed from the exposure rule of the current layer pattern, for example, the serial numbers 5 and 7 in FIG. 2 are removed; the serial numbers of the wafers having the serial numbers posterior to the serial number of the absent wafers in the sequence corresponding to the same bearing platform are sequentially advanced, and the serial number vacancies are filled, for example, the wafers numbered 9, 11, 13 . . . 21, 23 and 25 corresponding to the first bearing platform in FIG. 2 are advanced by two positions so as to obtain the exposure rule of the current layer pattern shown in FIG. 3.

At 140, the current layer pattern of each wafer in the current wafer group is exposed according to the exposure rule of the current layer pattern.

According to the technical scheme of the embodiment, the exposure rules of the first layer pattern or the previous layer pattern of each wafer in the current wafer group is extracted, where the exposure rules include the correspondences between the wafer serial numbers and bearing platforms, and the sequence of the wafer serial numbers identifies the exposure sequence of the corresponding wafers; the serial number of at least one absent wafer in the current wafer group is acquired according to the actual exposure information of the current layer pattern of each wafer in the current wafer group; the serial number of at least one absent wafer in the exposure rule of the current layer pattern is removed, the serial number of the wafer having the serial number posterior to the serial number of each of at least one absent wafer in the sequence corresponding to the same bearing platform is sequentially advanced, and the serial number vacancies are filled to obtain the exposure rule of the current layer pattern; and the current layer pattern of each wafer in the current wafer group is exposed according to the exposure rule of the current layer pattern, so that when there is an absent wafer, the wafers behind the absent wafer for the same bearing platform are sequentially exposed in advance, the situation that the bearing platforms are empty is avoided, and the productivity of the exposure machine is improved.

In some embodiments, the exposure of the current layer pattern of each wafer in the current wafer group according to the exposure rule of the current layer pattern may include: sequentially extracting the corresponding wafers in the wafer group and alternately placing the wafers on the first bearing platform and the second bearing platform to expose the current layer pattern according to the sequence of the wafer serial numbers in the exposure rule of the current layer pattern.

For example, before the current layer pattern of each wafer in the current wafer group is exposed according to the exposure rule of the current layer pattern, the method may further include: sequentially placing the wafers in the current wafer group into a wafer box according to the sequence of the serial numbers of the wafers in the current wafer group from small to large.

It should be noted that, in the exposure process of the wafers, the wafers in the wafer box are extracted one by one from one side, so that on one hand, the extraction difficulty of a manipulator is reduced, and on the other hand, when the wafer in the middle position is extracted, the damage to other wafers placed on the two sides of the wafer is avoided.

In the embodiment, after the current layer pattern of each wafer in the current wafer group is exposed according to the exposure rule of the current layer pattern, the method may further include: judging whether an exposure condition corresponding to the current layer pattern of each wafer in the next wafer group is the same as an exposure condition corresponding to the current layer pattern of each wafer in the current wafer group; and if the exposure condition corresponding to the current layer pattern of each wafer in the next wafer group is the same as the exposure condition corresponding to the current layer pattern of each wafer in the current wafer group, forming the exposure rule of the current layer pattern of the next wafer group according to the bearing platform information corresponding to the last exposed wafer in the current wafer group and the exposure condition of the current layer pattern of each wafer in the next wafer group, and exposing the current layer pattern of each wafer in the next wafer group according to the exposure rule of the current layer pattern of the next wafer group.

The exposure conditions may include the serial number of a photomask, an illumination mode, a photoresist type and the like used in the wafer exposure process.

It should be noted that, when the exposure conditions are the same, the current layer pattern of each wafer in the next wafer group may be exposed without changing any parameters of the exposure machine, in order to ensure the exposure continuity of the current wafer group and the next wafer group, the other bearing platform except the last exposed wafer in the current wafer group is configured to bear the first exposed wafer in the next wafer group, so that the exposure machine can work uninterruptedly in alternating time periods for the two wafer groups, and the reduction of the productivity is avoided.

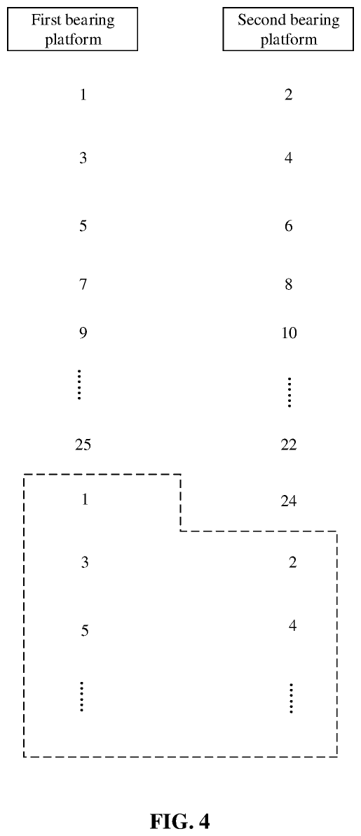

For example, FIG. 4 illustrates a diagram of correspondences between bearing platforms and wafer serial numbers provided in another embodiment of the disclosure. On the basis of FIG. 3, correspondences between the wafer serial numbers of wafers in the next wafer group and the bearing platforms are also included (within a dashed box in FIG. 4). Specifically, the last exposed wafer numbered 24 in the current wafer group corresponds to the second bearing platform, the wafer numbered 1 of the first exposed wafer in the next wafer group thus corresponds to the first bearing platform and is immediately arranged after the last wafer numbered 25 in the current wafer group corresponding to the first bearing platform.

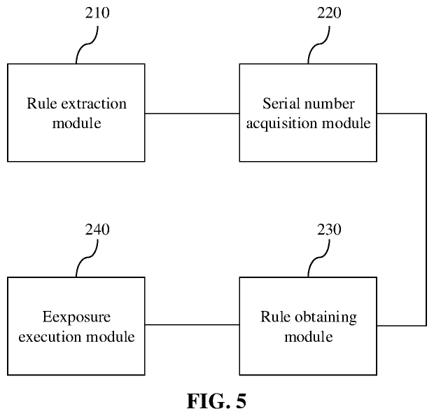

FIG. 5 illustrates a schematic diagram of an exposure device provided in an embodiment of the disclosure. As shown in FIG. 5, the exposure device may specifically include a rule extraction module 210, a serial number acquisition module 220, a rule obtaining module 230 and an exposure execution module 240. The rule extraction module 210 is configured to extract an exposure rule of a first layer pattern or a previous layer pattern of each wafer in the current wafer group, where the exposure rule includes correspondences between wafer serial numbers and bearing platforms, and the sequence of the wafer serial numbers identifies the exposure sequence of the corresponding wafers.

The serial number acquisition module 220 configured to acquire the serial number of at least one absent wafer in the current wafer group according to actual exposure information of the current layer pattern of each wafer in the current wafer group.

The rule obtaining module 230 is configured to remove the serial number of at least one absent wafer in the exposure rule of the current layer pattern, sequentially advance the serial number of a wafer having the serial number posterior to the serial number of each of at least one absent wafer in a sequence corresponding to the same bearing platform, and fill serial number vacancies to obtain the exposure rule of the current layer pattern.

The exposure execution module 240 is configured to expose the current layer pattern of each wafer in the current wafer group according to the exposure rule of the current layer pattern.

In the embodiment, the exposure execution module may specifically be configured to perform the following operation.

The corresponding wafers in a wafer box are sequentially extracted and the wafers are alternately placed on the first bearing platform and the second bearing platform to expose the current layer pattern according to the sequence of the wafer serial numbers in the exposure rule of the current layer pattern.

In the embodiment, the exposure device may further include a wafer placement module.

The wafer placement module is configured to sequentially place the wafers in the current wafer group into a wafer box according to the sequence the serial numbers of the wafers in the current wafer group from small to large before the current layer pattern of each wafer in the current wafer group is exposed according to the exposure rule of the current layer pattern.

In the embodiment, the exposure apparatus may further include an exposure condition judgment module and a rule formation module.

The exposure condition judgment module is configured to judge whether an exposure condition corresponding to the current layer pattern of each wafer in the next wafer group is the same as an exposure condition corresponding to the current layer pattern of each wafer in the current wafer group or not after the current layer pattern of each wafer in the current wafer group is exposed according to the exposure rule of the current layer pattern.

The rule formation module is configured to, when it is judged that the exposure condition corresponding to the current layer pattern of each wafer in the next wafer group is the same as the exposure condition corresponding to the current layer pattern of each wafer in the current wafer group, form the exposure rule of the current layer pattern of the next wafer group according to the bearing platform information corresponding to the last exposed wafer in the current wafer group and the exposure condition of the current layer pattern of each wafer in the next wafer group, and expose the current layer pattern of each wafer in the next wafer group according to the exposure rule of the current layer pattern of the next wafer group.

It should be noted that the above is only illustrative of the some embodiments of the disclosure and the technical principles employed. It will be understood by those skilled in the art that the disclosure is not limited to the specific embodiments described herein, and it is apparent that those skilled in the art can make various modifications and variations to the disclosure without departing from the scope of the disclosure. Therefore, although the disclosure has been described in more detail with reference to the above embodiments, the disclosure is not limited to the above embodiments, and may include other equivalent embodiments without departing from the spirit of the disclosure, and the scope of the disclosure is determined by the scope of the appended claims.

What is claimed is:

1. An exposure method, executed by an exposure machine, wherein the exposure machine comprises a first bearing platform and a second bearing platform, the first bearing platform and the second bearing platform work alternately, wherein the exposure method comprises:
extracting an exposure rule of a first layer pattern or a previous layer pattern of each wafer in a current wafer group, wherein the exposure rule comprises correspondences between wafer serial numbers and bearing platforms, and a sequence of the wafer serial numbers identifies an exposure sequence of corresponding wafers;
acquiring a serial number of at least one absent wafer in the current wafer group according to actual exposure information of a current layer pattern of each wafer in the current wafer group;
removing the serial number of the at least one absent wafer in the exposure rule of the current layer pattern, sequentially advancing a serial number of a wafer having the serial number posterior to the serial number of each of the at least one absent wafer in a sequence corresponding to a same bearing platform, and filling serial number vacancies to obtain the exposure rule of the current layer pattern; and
exposing the current layer pattern of each wafer in the current wafer group according to the exposure rule of the current layer pattern.

2. The exposure method of claim 1, wherein exposing the current layer pattern of each wafer in the current wafer group according to the exposure rule of the current layer pattern comprises:
sequentially extracting the corresponding wafers in a wafer box and alternately placing the wafers on the first bearing platform and the second bearing platform to expose the current layer pattern according to the sequence of the wafer serial numbers in the exposure rule of the current layer pattern.

3. The exposure method of claim 2, wherein before exposing the current layer pattern of each wafer in the current wafer group according to the exposure rule of the current layer pattern, the method further comprises:
sequentially placing the wafers in the current wafer group into a wafer box according to the sequence of the serial numbers of the wafers in the current wafer group from small to large.

4. The exposure method of claim 1, wherein after exposing the current layer pattern of each wafer in the current wafer group according to the exposure rule of the current layer pattern, the method further comprises:
judging whether an exposure condition corresponding to the current layer pattern of each wafer in a next wafer group is the same as an exposure condition corresponding to the current layer pattern of each wafer in the current wafer group or not; and
in a case where the exposure condition corresponding to the current layer pattern of each wafer in the next wafer group is the same as the exposure condition corresponding to the current layer pattern of each wafer in the current wafer group, forming the exposure rule of the current layer pattern of the next wafer group according to bearing platform information corresponding to a last exposed wafer in the current wafer group and the exposure condition of the current layer pattern of each wafer in the next wafer group, and exposing the current layer pattern of each wafer in the next wafer group according to the exposure rule of the current layer pattern of the next wafer group.

5. The exposure method of claim 4, wherein the exposure condition comprises a serial number of a photomask.

6. The exposure method of claim 1, wherein the wafer serial numbers corresponding to the same bearing platform are sequentially increased;
the wafer serial numbers corresponding to the first bearing platform and the second bearing platform which are alternately arranged in the exposure rule of the first layer pattern or the previous layer pattern are sequentially increased.

7. An exposure device, arranged in an exposure machine, wherein the exposure machine comprises a first bearing platform and a second bearing platform, the first bearing platform and the second bearing platform work alternately,
wherein the exposure device comprises:
a processor; and
a memory storing a computer program executable by the processor,
wherein when executing the computer program, the processor is configured to:
extract an exposure rule of a first layer pattern or a previous layer pattern of each wafer in a current wafer group, wherein the exposure rule comprises correspondences between wafer serial numbers and bearing platforms, and a sequence of the wafer serial numbers identifies an exposure sequence of corresponding wafers;
acquire a serial number of at least one absent wafer in the current wafer group according to actual exposure information of a current layer pattern of each wafer in the current wafer group;
remove the serial number of the at least one absent wafer in the exposure rule of the current layer pattern, sequentially advance a serial number of a wafer having the serial number posterior to the serial number of each of the at least one absent wafer in a sequence corresponding to a same bearing platform, and fill serial number vacancies to obtain the exposure rule of the current layer pattern; and
expose the current layer pattern of each wafer in the current wafer group according to the exposure rule of the current layer pattern.

8. The exposure device of claim 7, wherein when exposing the current layer pattern of each wafer in the current wafer group according to the exposure rule of the current layer pattern, the processor is configured to:
sequentially extract the corresponding wafers in a wafer box and alternately place the wafers on the first bearing platform and the second bearing platform to expose the current layer pattern according to the sequence of the wafer serial numbers in the exposure rule of the current layer pattern.

9. The exposure device of claim 8, wherein before exposing the current layer pattern of each wafer in the current wafer group according to the exposure rule of the current layer pattern, the processor is further configured to:
sequentially place the wafers in the current wafer group into a wafer box according to the sequence of the serial numbers of the wafers in the current wafer group from small to large.

10. The exposure device of claim 7, wherein after exposing the current layer pattern of each wafer in the current wafer group according to the exposure rule of the current layer pattern, the processor is further configured to:
judge whether an exposure condition corresponding to the current layer pattern of each wafer in a next wafer group is the same as an exposure condition corresponding to the current layer pattern of each wafer in the current wafer group or not; and
in a case where the exposure condition corresponding to the current layer pattern of each wafer in the next wafer group is the same as the exposure condition corresponding to the current layer pattern of each wafer in the current wafer group, form the exposure rule of the current layer pattern of the next wafer group according to bearing platform information corresponding to a last exposed wafer in the current wafer group and the exposure condition of the current layer pattern of each wafer in the next wafer group, and expose the current layer pattern of each wafer in the next wafer group according to the exposure rule of the current layer pattern of the next wafer group.

11. The exposure device of claim 10, wherein the exposure condition comprises a serial number of a photomask.

12. The exposure device of claim 7, wherein the wafer serial numbers corresponding to the same bearing platform are sequentially increased;
the wafer serial numbers corresponding to the first bearing platform and the second bearing platform which are alternately arranged in the exposure rule of the first layer pattern or the previous layer pattern are sequentially increased.

13. A non-volatile computer-readable storage medium, applied to an exposure machine, wherein the exposure machine comprises a first bearing platform and a second bearing platform, the first bearing platform and the second bearing platform work alternately,
wherein the non-volatile computer-readable storage medium stores a computer program, and wherein when executed by a processor arranged in the exposure machine, the computer program is configured to:
extract an exposure rule of a first layer pattern or a previous layer pattern of each wafer in a current wafer group, wherein the exposure rule comprises correspondences between wafer serial numbers and bearing platforms, and a sequence of the wafer serial numbers identifies an exposure sequence of corresponding wafers;
acquire a serial number of at least one absent wafer in the current wafer group according to actual exposure information of a current layer pattern of each wafer in the current wafer group;
remove the serial number of the at least one absent wafer in the exposure rule of the current layer pattern, sequentially advance a serial number of a wafer having the serial number posterior to the serial number of each of the at least one absent wafer in a sequence corresponding to a same bearing platform, and fill serial number vacancies to obtain the exposure rule of the current layer pattern; and
expose the current layer pattern of each wafer in the current wafer group according to the exposure rule of the current layer pattern.

14. The non-volatile computer-readable storage medium of claim 13, wherein when exposing the current layer pattern of each wafer in the current wafer group according to the exposure rule of the current layer pattern, the computer program is configured to:
sequentially extract the corresponding wafers in a wafer box and alternately place the wafers on the first bearing platform and the second bearing platform to expose the current layer pattern according to the sequence of the wafer serial numbers in the exposure rule of the current layer pattern.

15. The non-volatile computer-readable storage medium of claim 14, wherein before exposing the current layer pattern of each wafer in the current wafer group according to the exposure rule of the current layer pattern, the computer program is further configured to:
sequentially place the wafers in the current wafer group into a wafer box according to the sequence of the serial numbers of the wafers in the current wafer group from small to large.

16. The non-volatile computer-readable storage medium of claim 13, wherein after exposing the current layer pattern of each wafer in the current wafer group according to the exposure rule of the current layer pattern, the computer program is further configured to:
judge whether an exposure condition corresponding to the current layer pattern of each wafer in a next wafer group is the same as an exposure condition corresponding to the current layer pattern of each wafer in the current wafer group or not; and
in a case where the exposure condition corresponding to the current layer pattern of each wafer in the next wafer group is the same as the exposure condition corresponding to the current layer pattern of each wafer in the current wafer group, form the exposure rule of the current layer pattern of the next wafer group according to bearing platform information corresponding to a last exposed wafer in the current wafer group and the exposure condition of the current layer pattern of each wafer in the next wafer group, and expose the current layer pattern of each wafer in the next wafer group according to the exposure rule of the current layer pattern of the next wafer group.

17. The non-volatile computer-readable storage medium of claim 16, wherein the exposure condition comprises a serial number of a photomask.

18. The non-volatile computer-readable storage medium of claim 13, wherein the wafer serial numbers corresponding to the same bearing platform are sequentially increased;
the wafer serial numbers corresponding to the first bearing platform and the second bearing platform which are alternately arranged in the exposure rule of the first layer pattern or the previous layer pattern are sequentially increased.
